(19) United States
(12) Patent Application Publication
(10) Pub. No.: US 2016/0014898 A1
(43) Pub. Date: Jan. 14, 2016

(54) PRINTED WIRING BOARD

(71) Applicant: IBIDEN CO., LTD., Ogaki-shi (JP)

(72) Inventors: Takema Adachi, Ogaki-shi (JP); Wataru Nakamura, Ogaki-shi (JP); Tomoyoshi Hirabayashi, Ogaki-shi (JP)

(73) Assignee: IBIDEN CO., LTD., Ogaki-shi (JP)

(21) Appl. No.: 14/798,550

(22) Filed: Jul. 14, 2015

(30) Foreign Application Priority Data
Jul. 14, 2014 (JP) 2014-144323

(51) Int. Cl. H05K 1/14; H05K 1/09; H01L 23/498; H05K 1/18

(52) U.S. Cl. CPC H05K 1/144; H05K 1/185; H05K 1/09; H01L 23/49811; H01L 23/49838; H01L 23/49866; H01L 23/49816; H05K 2201/0326; H05K 2201/0364; H05K 2201/09372; H05K 2201/042

(57) ABSTRACT

A printed wiring board includes a first circuit substrate having first pads and second pads such that the first pads are positioned to mount an electronic component on the first circuit substrate and that the second pads are positioned to electrically connect the first circuit substrate to a second circuit substrate, and metal posts including plating material and formed on the second pads respectively such that the metal posts are positioned to mount the second circuit substrate on the first circuit substrate. Each of the metal posts has a height h1 and a thickness b such that the metal posts have a value h1/b which is greater than 0.1 and smaller than 1.0 where the value h1/b is obtained by dividing the height h1 by the thickness b.

### CROSS-REFERENCE TO RELATED APPLICATIONS

The present application is based upon and claims the benefit of priority to Japanese Patent Application No. 2014-144323, filed Jul. 14, 2014, the entire contents of which are incorporated herein by reference.

### BACKGROUND OF THE INVENTION

1. Field of the Invention

The present invention relates to a printed wiring board having a metal post for mounting a second circuit substrate.

2. Description of Background Art

U.S. Pat. No. 7,723,834 B2 describes a POP package and a method for manufacturing the POP package. In U.S. Pat. No. 7,723,834 B2, semiconductor packages are connected by a lead line. The entire contents of this publication are incorporated herein by reference.

### SUMMARY OF THE INVENTION

According to one aspect of the present invention, a printed wiring board includes a first circuit substrate having first pads and second pads such that the first pads are positioned to mount an electronic component on the first circuit substrate and that the second pads are positioned to electrically connect the first circuit substrate to a second circuit substrate, and metal posts including plating material and formed on the second pads respectively such that the metal posts are positioned to mount the second circuit substrate on the first circuit substrate. Each of the metal posts has a height h1 and a thickness b such that the metal posts have a value h1/b which is greater than 0.1 and smaller than 1.0 where the value h1/b is obtained by dividing the height h1 by the thickness b.

According to another aspect of the present invention, a package on package substrate includes a printed wiring board, a second circuit substrate mounted on the printed wiring board, and an electronic component mounted on the printed wiring board such that the electronic component is positioned in a space formed between the printed wiring board and the second circuit substrate. The printed wiring board includes a first circuit substrate having first pads and second pads such that the first pads are positioned to mount the electronic component on the first circuit substrate and that the second pads are positioned to electrically connect the printed wiring board to the second circuit substrate, and metal posts including plating material and formed on the second pads respectively such that the metal posts are positioned to mount the second circuit substrate on the first circuit substrate, and each of the metal posts has a height h1 and a thickness b such that the metal posts have a value h1/b which is greater than 0.1 and smaller than 1.0 where the value h1/b is obtained by dividing the height h1 by the thickness b.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 A is a cross-sectional view of a printed wiring board according to a first embodiment of the present invention;

FIG. 1B is a cross-sectional view of a modified example of the printed wiring board of the first embodiment;

FIG. 2 is a cross-sectional view of an applied example of the printed wiring board of the first embodiment;

FIG. 3A is a plan view of a mounting surface of a first circuit substrate;

FIG. 3B is a plan view of a mounting surface of the printed wiring board;

FIG. 4A-4D are manufacturing process diagrams of the printed wiring board according to the first embodiment;

FIGS. 5A and 5B are manufacturing process diagrams of the printed wiring board according to the first embodiment;

FIGS. 5C and 5D are manufacturing process diagrams of the applied example;

FIGS. 6A and 6B are manufacturing process diagrams of the printed wiring board according to the modified example of the first embodiment;

FIGS. 6C and 6D are manufacturing process diagrams of a printed wiring board according to a second embodiment; and

FIG. 7A-7D are manufacturing process diagrams of the printed wiring board according to the second embodiment.

### DETAILED DESCRIPTION OF THE EMBODIMENTS

The embodiments will now be described with reference to the accompanying drawings, wherein like reference numerals designate corresponding or identical elements throughout the various drawings.

### First Embodiment

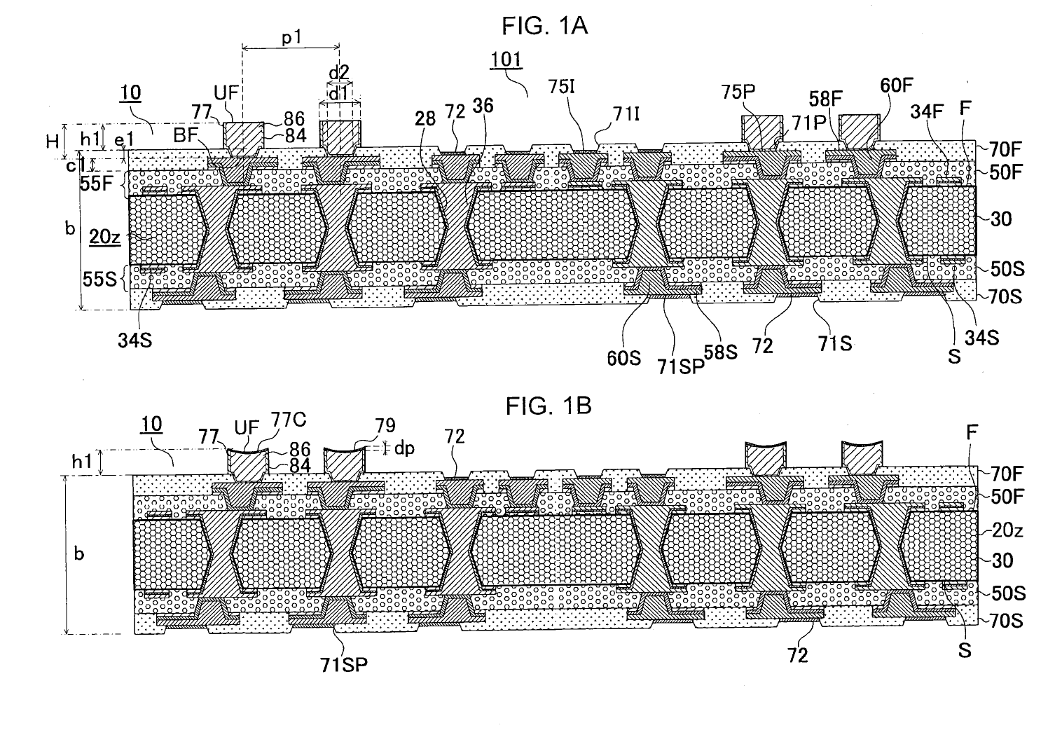

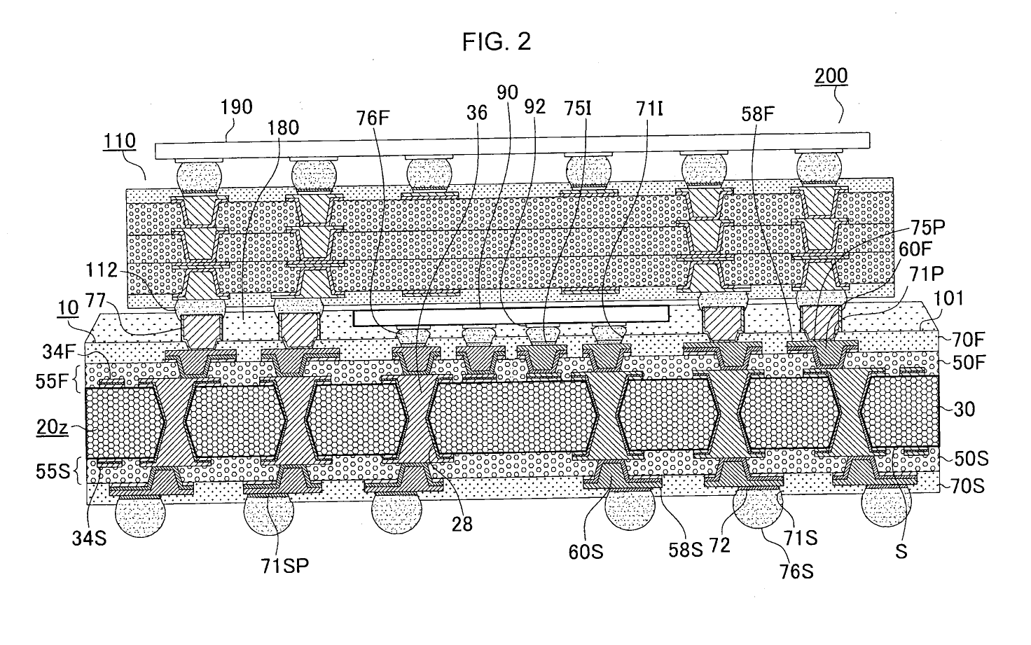

A printed wiring board 10 according to a first embodiment of the present invention is illustrated in FIG. 1A. An applied example 200 of the printed wiring board 10 is illustrated in FIG. 2.

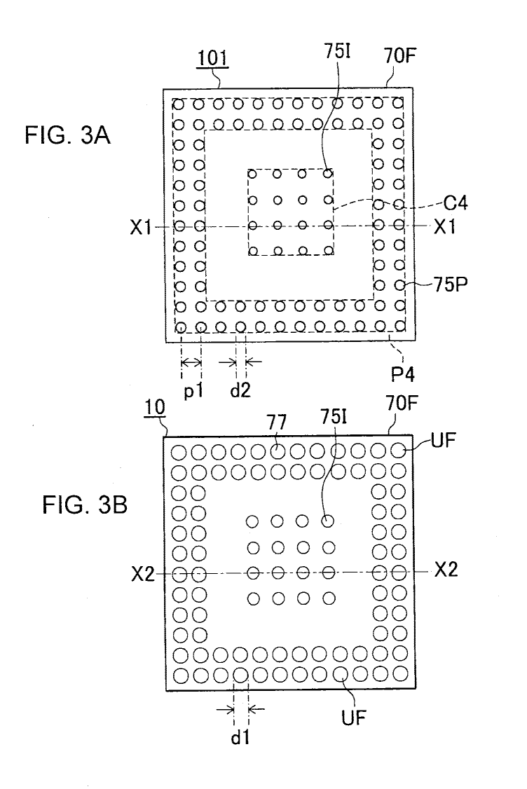

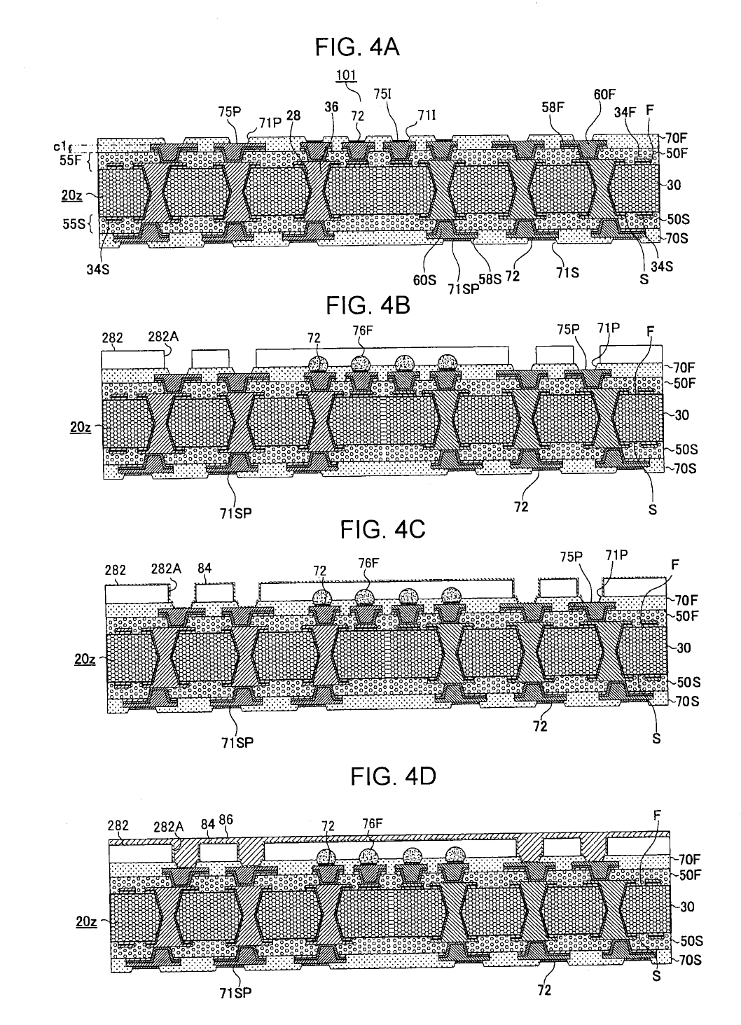

The printed wiring board 10 is formed by a first circuit substrate (lower substrate) 101 illustrated in FIG. 4A and a metal post 77 illustrated in FIG. 1A. The printed wiring board 10 or the first circuit substrate 101 has a pad (first pad) (75I) for mounting an electronic component 90 such as an IC chip and a pad (second pad) (75P) for mounting a second circuit substrate (upper substrate) 110. The second circuit substrate 110 and the second pad are electrically connected. An electronic component 190 such as a memory is mounted on the second circuit substrate 110. A pad group (C4) (see FIG. 3A) is formed by multiple pads (75I). The pad group (C4) is formed at substantially a center of the printed wiring board 10 or the first circuit substrate 101. The second pad (75P) is formed in an outer periphery region (P4) (see FIG. 3A) around the pad group (C4). The metal post 77 is formed on the second pad. The upper substrate and the lower substrate are connected by the metal post. The metal post 77 has an upper surface (UF). The metal post is formed by a seed layer 84 and an electrolytic plating film 86 on the seed layer 84. The electrolytic plating film 86 is formed in a space formed by the seed layer 84. The seed layer is formed on a side wall and a lower surface of the electrolytic copper plating film 86 that forms the metal post 77. The lower surface of the electrolytic plating film opposes the second pad (75P). The seed layer is formed on the side wall of the electrolytic copper plating film 86 that protrudes from a solder resist layer.

The height (h1) is a length of the metal post (a protruding portion of the metal post) that protrudes from an upper surface of the solder resist layer (70F).

As illustrated in FIG. 1 A, the metal post has the upper surface (UF). Further, the metal post 77 has a lower surface (BF) on an opposite side of the upper surface. The lower surface (BF) is in contact with the second pad. It is preferable that the portion of the metal post 77 that protrudes from an upper surface of the solder resist layer have a shape of a circular cylinder. The protruding portion of the metal post has a shape of a right circular cylinder. The metal post 77 electrically connects the lower substrate 101 and the upper substrate 110.

A length (H) of the metal post is a distance between an upper surface of the second pad and the upper surface (UF) of the metal post.

FIG. 3A illustrates a mounting surface of the first circuit substrate 101. FIG. 3A illustrates the upper side solder resist layer (70F) and the first pads (75I) and the second pads (75P) that are exposed from openings of the solder resist layer (70F). A pitch (p1) between adjacent second pads is 0.3 mm or less. A distance between centroids of the adjacent pads is the pitch. Or, a distance between centers of the adjacent pads is the pitch.

Even when the pitch (p1) is 0.3 mm or less, a distance between the lower substrate 101 and the upper substrate 110 is ensured by the metal post 77. Further, insulation between the adjacent pads is ensured.

The printed wiring board 10 or the first circuit substrate 101 of the first embodiment may be a printed wiring board having a core substrate, or may be a coreless substrate. A printed wiring board having a core substrate and a method for manufacturing the printed wiring board are described, for example, in JP2007227512A. The entire contents of this publication are incorporated herein by reference. A coreless substrate and a method for manufacturing the coreless substrate are described, for example, in JP2005236244A. The coreless substrate has interlayer resin insulating layers and conductor layers that are alternately laminated. All of the interlayer resin insulating layers have a thickness of, for example, 60 μm or less.

The upper substrate may be a printed wiring board having a core substrate or may be a coreless substrate.

As illustrated in FIGS. 1A and 4A, the printed wiring board 10 or the first circuit substrate 101 of the first embodiment has a core substrate 30. The core substrate 30 has: an insulating substrate (20z) that has a first surface (F) and a second surface (S) that is on an opposite side of the first surface; a first conductor layer (34F) that is formed on the first surface (F) of the insulating substrate; and a second conductor layer (34S) that is formed on the second surface of the insulating substrate. The core substrate further has a through-hole conductor 36 that is obtained by filling a through hole 28 for the through-hole conductor with a plating film, the through hole 28 being formed in the insulating substrate (20z). The through-hole conductor 36 connects the first conductor layer (34F) and the second conductor layer (34S). A first surface of the core substrate and the first surface of the insulating substrate are the same surface; and a second surface of the core substrate and the second surface of the insulating substrate are the same surface.

An interlayer resin insulating layer (uppermost interlayer resin insulating layer) (50F) is formed on the first surface (F) of the core substrate 30. A conductor layer (uppermost conductor layer) (58F) is formed on the interlayer resin insulating layer (50F). The conductor layer (58F), the first conductor layer (34F) and the through-hole conductor 36 are connected by a via conductor (uppermost via conductor) (60F) that penetrates through the interlayer resin insulating layer (50F). An upper side build-up layer (55F) is formed by the interlayer resin insulating layer (50F), the conductor layer (58F) and the via conductor (60F). In the first embodiment, the upper side build-up layer is a single layer. The uppermost conductor layer has the pads (75I, 75P) illustrated in FIGS. 3A and 4A.

An interlayer resin insulating layer (lowermost interlayer resin insulating layer) (50S) is formed on the second surface (S) of the core substrate 30. A conductor layer (lowermost conductor layer) (58S) is formed on the interlayer resin insulating layer (50S). The conductor layer (58S), the second conductor layer (34S) and the through-hole conductor are connected by a via conductor (lowermost via conductor) (60S) that penetrates through the interlayer resin insulating layer (50S). A lower side build-up layer (55S) is formed by the interlayer resin insulating layer (50S), the conductor layer (58S) and the via conductor (60S). In the first embodiment, the lower side build-up layer is a single layer. The lowermost conductor layer has a BGA pad (71 SP) for connecting to a motherboard.

An upper side solder resist layer (70F) is formed on the upper side build-up layer, and a lower side solder resist layer (70S) is formed on the lower side build-up layer. The solder resist layer (70F) has an opening (first opening) (71I) for exposing the first pad (75I) and an opening (second opening) (71P) for exposing the second pad (75P). The solder resist layer (70S) has an opening (71S) for exposing the BGA pad (71SP). Protective films 72 are respectively formed on the first pad (75I) and the BGA pad (71SP). A protective film may also be formed on the second pad (75P). The protective film is a film for preventing oxidation of the pad. Examples of the protective film include Ni/Au, Ni/Pd/Au, Sn and OSP. Pd/Au is drop impact resistant.

As illustrated in FIG. 2, connection members (76F, 76S) such as a solder bump and a Sn film for connecting the electronic component 90 and a motherboard are formed on the first pad (75I) and the BGA pad (71SP).

The connection members (76F, 76S) are formed on the protective films 72. The connection members may also be directly formed on the pads. When the protective film is an OSP, after the OSP is removed, the connection members are directly formed on the pads. It is also possible that there is not a connection member.

The first circuit substrate illustrated in FIG. 4A is also referred to as an intermediate substrate 101 of the printed wiring board of the first embodiment in the present specification. FIG. 4A is a cross-sectional view of the intermediate substrate 101. FIG. 3A illustrates the mounting surface of the first circuit substrate (intermediate substrate). FIG. 3A is a plan view of the first circuit substrate when the first circuit substrate is observed from the upper side solder resist side. FIG. 3A illustrates the upper side solder resist layer (70F) and the pads (75I, 75P) that are exposed from the openings (71I, 71P) of the solder resist layer. A cross section of the intermediate substrate 101 along a line X1-X1 of FIG. 3A is illustrated in FIG. 4A. As illustrated in FIG. 3A, the first pads (75I) for mounting the electronic component 90 are formed in a substantially central region of the first circuit substrate 101. An area containing all the first pads is a C4 area. A dotted line is drawn along an outer periphery of the C4 area. As illustrated in FIG. 3A, the second pads (75P) for mounting the second circuit substrate 110 are formed on an outer side of the first pads (75I). The second pads (75P) are formed in an outer periphery region of the first circuit substrate 101. In FIG. 3A, the second pads (75P) surround the first pads. However, the second pads (75P) may also be formed along two sides of the first circuit substrate. It is preferable that the second pads be formed on two opposing sides.

FIG. 3B illustrates a mounting surface of the printed wiring board of FIG. 1A. FIG. 3B is a plan view of the printed wiring board obtained by observing the printed wiring board 10 from the upper side solder resist side. In FIG. 3B, the upper surface of the upper side solder resist layer (70F), the first pads (75I), and the upper surfaces (UF) of the metal posts 77 on the second pads (75P) are illustrated.

A cross section of the printed wiring board 10 along a line X2-X2 of FIG. 3B is illustrated in FIG. 1A.

A diameter (d1) of the metal post 77 is greater than a diameter (d2) of the second pad (75P). As illustrated in FIG. 1A, the diameter (d1) is a diameter of the protruding portion of the metal post. It is preferable that a ratio (d1/d2) between the diameter (d1) of the metal post and the diameter (d2) of the pad (75P) is in a range from 0.5 to 0.9. The pitch between the pads can be reduced. Even when the pitch (p1) is 0.3 mm or less, connection reliability between the lower substrate and the upper substrate is high. Further, insulation reliability between the metal posts is high. The pitch (p1) is 100 μm-300 μm. When the pitch (p1) is less than 100 μm, the insulation reliability between the metal posts is likely to decrease. Further, since the metal post becomes thin, the connection reliability between the upper substrate and the lower substrate is decreased. When the pitch (p1) exceeds 300 μm, a size of the printed wiring board 10 is increased. Therefore, stress acting on the metal post is increased and thus the connection reliability between the upper substrate and the lower substrate is decreased. As illustrated in FIG. 3A, the pitch (p1) is a distance between centers of adjacent second pads. Or, the pitch (p1) is a distance between centroids of the adjacent second pads.

As illustrated in FIG. 1A, the metal post has a height (h1) and a length (H). When the pitch (p1) is 0.3 mm or less, the height (h1) of the metal post 77 is 50 μm-150 μm. As illustrated in FIG. 1A, the height (h1) of the metal post is a distance between the upper surface (UF) of the metal post and the upper surface of the upper side solder resist layer (70F). It is preferable that the height (h1) be less than 100 μm. A distance (e1) between the upper surface of the solder resist layer (70F) and the upper surface of the pad (75P) is 15 μm-30 μm.

The length (H) of the metal post 77 is 65 μm-180 μm. The length (H) is a distance between the upper surface (UF) of the metal post 77 and the upper surface of the second pad (75P). The length (H) is equal to a sum of the height (h1) and the distance (e1). The pad (75P) has a thickness (c1) of 5 μm-20 μm. A ratio (H/c1) of the length (H) and the thickness (e1) is 5 or more and 20 or less.

It is preferable that an aspect ratio (length (H)/diameter (d1)) (MR) of the metal post 77 is smaller than 1.5. When the aspect ratio (MR) is less than 1.5, a center of gravity of the metal post is low. A bottom area (contact area between the lower surface (BF) and the pad (75P)) with respect to the length of the metal post is large. The metal post becomes stronger against a force acting in a direction parallel to the bottom surface (lower surface) (BF) of the metal post.

When the aspect ratio (MR) is less than 1, the metal post of the present embodiment is thick and short. The rigidity of the metal post is increased. Therefore, a deformation amount of the metal post in a heat cycle is small. Warpage of a POP substrate is decreased. A POP substrate that can be easily mounted on a motherboard can be provided. The lower substrate and the upper substrate are unlikely to deteriorate. Reliability of the lower substrate and the upper substrate can be improved. When the aspect ratio (MR) is less than 1, the metal post is unlikely to deteriorate due to fatigue. A crack is unlikely to occur in the metal post.

When the aspect ratio (MR) is 0.6 or less, the diameter of the metal post becomes large. Accordingly, the diameter of the second pad and the diameter of the second opening also become large. Therefore, sizes of the lower substrate and the upper substrate become large. As a result, thermal stress acting on the metal post also becomes large.

Due the thermal stress acting on the metal post, the metal post deteriorates. Or, the connection reliability between the metal post and the lower substrate and the connection reliability between the metal post and the upper substrate are decreased. A deformation amount of the POP substrate due to heat becomes large. The connection reliability between the motherboard and the POP substrate is decreased. It becomes difficult to mount the POP substrate on the motherboard.

When the aspect ratio (MR) is 0.6 or less, stress due to a difference between a physical property of the upper substrate and a physical property of the lower substrate becomes large. Therefore, the metal post deteriorates. Examples of the physical property include a thermal expansion coefficient and a Young's modulus.

Heat from an IC chip mounted on the lower substrate is transmitted via a conductor circuit in the lower substrate to the metal post. The heat can be released via a side surface of the metal post to outside. However, when the aspect ratio ((MR)) is 0.6 or less, the distance between the lower substrate and the upper substrate becomes short. The metal post is thick. Therefore, the heat is accumulated in the metal post. Temperatures of the lower substrate 101 and the POP substrate 200 are likely to rise. The thermal stress acting on the metal post becomes large. Warpages of the lower substrate and the POP substrate become large. Further, the heat of the IC chip is likely to be transmitted to the memory on the upper substrate. The memory on the upper substrate is likely to malfunction.

As illustrated in FIG. 2, the lower substrate 101 and the upper substrate 110 are connected by the metal post 77 that has high rigidity, and a joining member 112. It is preferable that the joining member is solder. The joining member has rigidity lower than that of the metal post. A thermal stress between the upper substrate and the lower substrate is relaxed by the joining member. Strength of an electronic device that has the upper substrate and the lower substrate is maintained by the metal post.

It is preferable that a ratio ((the height (h1) of the metal post)/(the distance (b)) (h1/b) of the height (h1) of the metal post to the thickness (distance) (b) of the first circuit substrate greater than 0.1 and smaller than 1.0. As illustrated in FIG. 1A, the thickness (b) of the first circuit substrate is a distance between an uppermost surface and a lowermost surface of the first circuit substrate.

The second circuit substrate is mounted on the first circuit substrate via the metal post by reflow or the like. Due to reflow, the temperature of the first circuit substrate becomes high. When the temperature of the first circuit substrate becomes high, the rigidity of the first circuit substrate decreases. Further, the metal post is formed in an outer periphery region of the first circuit substrate. Therefore, due to a weight of the metal post, at the high temperature, warpage is likely to occur in the first circuit substrate. When the metal post is long, the weight of the metal post becomes large. When the ratio (h1/b) is 1 or more, due to the weight of the metal post, yield of mounting the second circuit substrate on the first circuit substrate is decreased. Further, the connection strength between the metal post and the second circuit substrate becomes insufficient. Therefore, due to a thermal stress, the connection reliability between the first circuit substrate and the second circuit substrate via the metal post is decreased.

The metal post has a shape of a cylinder. Therefore, the thermal stress due to a difference between a physical property of the first circuit substrate and a physical property of the second circuit substrate is relaxed by the metal post. The physical property is a thermal expansion coefficient or a Young's modulus. When the metal post is long, a deformation amount of the metal post due to the thermal stress is increased. When the metal post is subjected to repeated thermal stress, the metal post deteriorates due to fatigue. When the ratio (h1/b) is 1 or more, deterioration of the metal post becomes significant.

When the ratio (h1/b) is 0.1 or less, the metal post becomes short. The rigidity of the metal post is increased. Therefore, the stress relaxation effect due to the metal post is decreased. Therefore, the connection reliability between the first circuit substrate and the second circuit substrate via the metal post is decreased. The reliability of the POP substrate is decreased. When the ratio (h1/b) is 0.1 or less, the distance between the lower substrate and the upper substrate becomes short. An electronic component such as a sophisticated IC chip has a thick thickness. Therefore, it is difficult to mount a sophisticated electronic component on the lower substrate.

When the ratio (h1/b) is more than 0.1 and less than 1.0, the reliability of the POP substrate is increased. Warpage of the first circuit substrate is decreased. Further, a printed wiring board having a post for providing a POP substrate of high reliability can be provided.

### Manufacturing Method of First Embodiment

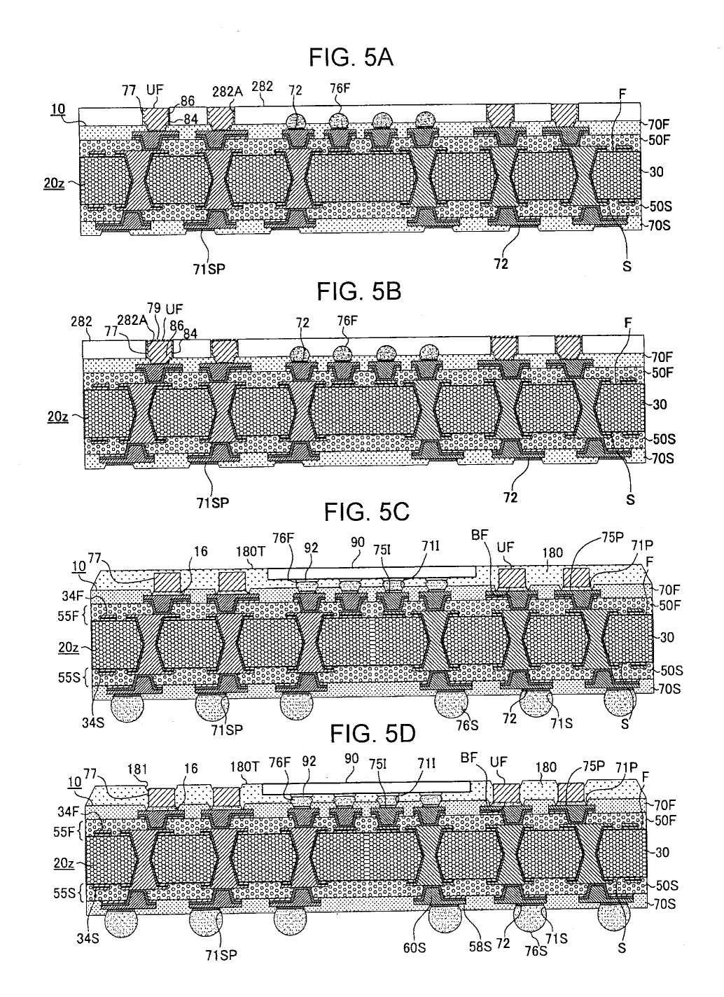

A method for manufacturing the printed wiring board 10 according to the first embodiment illustrated in FIG. 1 A is illustrated in FIGS. 4A-4D and 5A-5D. In the first embodiment, the metal post is formed by plating.

FIG. 4A illustrates the intermediate substrate 101. The intermediate substrate illustrated in FIG. 4A has the pad (75P), and the metal post is mounted on the pad (75P). The intermediate substrate illustrated in FIG. 4A may be manufactured, for example, using a method described in Japanese Patent Laid-Open Publication No. 2012-069926. The entire contents of this publication are incorporated herein by reference. An OSP (Organic Solderability Preservative) film 72 is formed on the pad (75I) that is exposed by the opening (71I) of the solder resist layer (70F) of the intermediate substrate, and on the pad (71SP) that is exposed by the opening (71S) of the solder resist layer (70S). Here, in place of the OSP film, it is also possible that a protective film such as a nickel-gold film or a nickel-palladium-gold film is formed.

A solder bump (76F) is formed on the first pad (71I) of the intermediate substrate 101. Thereafter, as illustrated in FIG. 4B, a plating resist 282 is formed on the solder bump (76F) and on the solder resist layer (70F). The plating resist 282 has an opening (282A) for exposing the second pad (75P). The opening (282A) has a size larger than that of the second opening (71P). A ratio of the size of the opening (282A) to the size of the opening (71P) ((the size of the opening (282A))/(size of the opening (71P))) is in a range of from 1.2 to 1.5. The connection reliability between the metal post 77 and the pad (75P) is increased. The BGA pad and the lower side solder resist layer are covered by a protective sheet. However, the protective sheet is not depicted in the drawings. A seed layer 84 is formed on the plating resist 282, in the opening (282A) and on the second pad (75P) by sputtering (FIG. 4C). The seed layer is formed by a Ti film and a Cu film on the Ti film. The seed layer can be formed by electroless copper plating.

An electrolytic copper plating film 86 is formed on the seed layer 84. As illustrated in FIG. 4D, the electrolytic copper plating film 86 is formed in a space formed by the seed layer. The opening (282A) is filled with the electrolytic copper plating film 86. In this case, the electrolytic plating film 86 is formed on the plating resist 282 at the same time (FIG. 4D). The electrolytic plating film 86 on the plating resist 282 is removed by etching (FIG. 5A).

A protective film 79 is formed on the upper surface (UF) of the metal post 77 (FIG. 5B). The protective film 79 is a film for preventing oxidation of the metal post 77. An example of the protective film is Ni/Au. As the protective film, Sn, solder, OSP and the like can be used, in addition to Ni/Au. The protective film has a thickness of about 2 μm. The thickness of the protective film is included in the height and length of the metal post. The plating resist 282 is removed. The side surface of the metal post 77 is exposed. The protective sheet is removed. The printed wiring board 10 of the first embodiment is completed (FIG. 1A). The ratio (h1/b) of the first embodiment is 0.8. The metal post is formed by plating. In the first embodiment, the protective film is formed only on the upper surface of the metal post. When a joining member such as a solder is formed on the upper surface of the metal post, the joining member is formed only on the upper surface of the metal post. The joining member does not wetly spread to the side wall of the metal post. Therefore, the distance between the metal posts can be narrowed. The pitch of the second pads (75P) can be reduced. The size of the first circuit substrate is decreased. Warpage of the first circuit substrate or the POP substrate is decreased. The metal post does not deteriorate in a heat cycle.

### Manufacturing Method of Applied Example

A method for manufacturing the applied example (POP substrate) illustrated in FIG. 2 is illustrated in FIGS. 5C and 5D. An electrode 92 of the IC chip 90 is connected to the solder bump (76F) of the printed wiring board 10. The IC chip 90 is mounted on the printed wiring board 10. Thereafter, mold resin 180 is formed on the mounting surface of the printed wiring board 10. The metal post 77 and the electronic component are molded by the mold resin (FIG. 5C). The metal post 77 is embedded in the mold resin 180. An opening 181 that expose the upper surface (UF) of the metal post 77 and the side wall connecting to the upper surface is formed in the mold resin 180 (FIG. 5D). The side surface of the metal post is partially exposed. The opening 181 is formed using laser. As illustrated in FIG. 5D, the opening 181 is tapered from an upper surface of the mold resin toward the metal post. The joining member 112 such as a solder is formed on the metal post that is exposed from the opening 181. The upper substrate 110 is joined to the metal post 77 via the solder 112. The upper substrate is mounted on the printed wiring board 10 (FIG. 2). The POP (Package on Package) substrate is completed. It is also possible that the POP substrate does not have the solder bump (76S) on the BGA pad (71SP).

In the example of the POP substrate of FIG. 2, the opening 181 is filled with the solder 112 that connects the upper substrate and the metal post. The solder and the metal post are bonded via the upper surface and a portion of the side wall of the metal post. A bonding strength between the two is increased. The connection reliability via the metal post is increased. As illustrated in FIGS. 5C and 5D, the upper surface (180T) of the mold resin is positioned above the upper surface (UF) of the metal post. After the formation of the opening 181, by forming a protective film on the metal post, a protective film can be formed on the upper surface and a portion of the side wall of the metal post that are exposed from the opening 181. In this case, the solder wetly spreads to the side wall of the metal post.

### Modified Example of First Embodiment

FIG. 1B illustrates a printed wiring board according to a modified example of the first embodiment.

In the modified example, the upper surface (UF) of the metal post 77 has a concave portion (77C). Therefore, adhesion between the joining member 112 and the upper surface of the metal post illustrated in FIG. 2 is high. The concave portion (77C) has a depth (dp) of 5-30 μm.

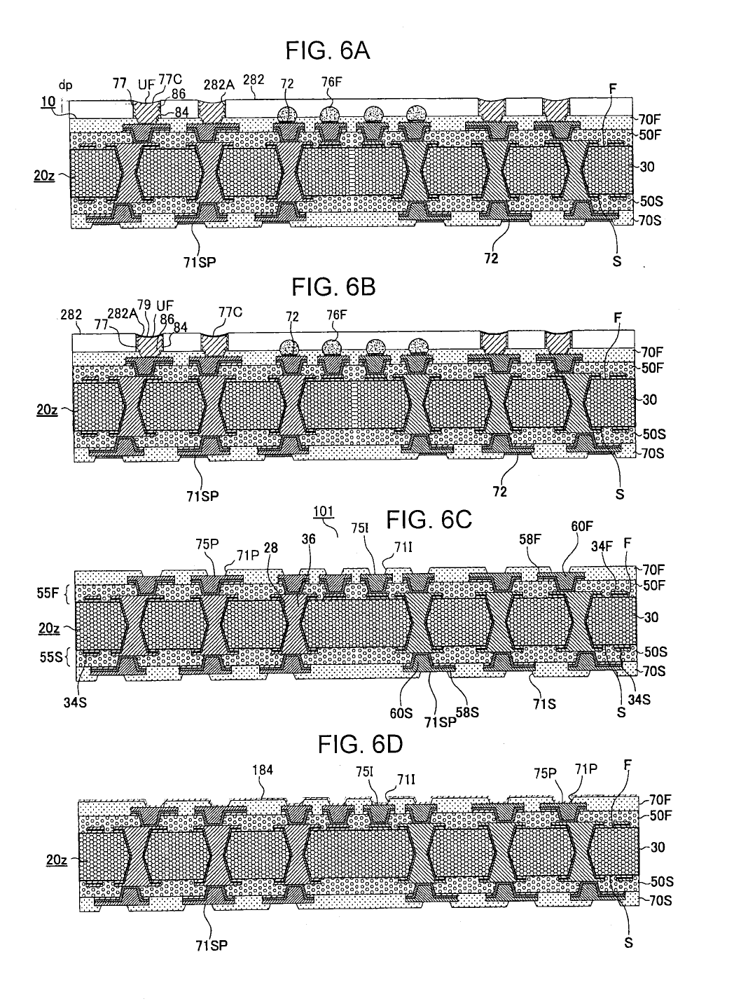

FIGS. 6A and 6B illustrate a method for manufacturing the printed wiring board according to the modified example of the first embodiment.

Similar to the first embodiment, the intermediate substrate illustrated in FIG. 5A is manufactured. In the modified example, the electrolytic plating film 86 on the plating resist 282 is removed. Further, the electrolytic plating film 86 in the opening (282A) is removed by etching or the like. The concave portion (77C) is formed on the upper surface of the metal post (FIG. 6A). The depth of the concave portion (77C) is adjusted by adjusting etching time or the like. A protective film 79 is formed on the upper surface of the metal post (FIG. 6B). The plating resist 282 is removed. The printed wiring board 10 according to the modified example of the first embodiment is completed (FIG. 1B).

In the modified example of the first embodiment, the ratio (h1/b) of the height (h1) of the metal post to the thickness (distance) (b) of the first circuit substrate is greater than 0.1 and smaller than 1.0. The ratio (h1/b) is 0.6. The thickness of the protective film 79 is included in the height (h1) of the metal post.

### Second Embodiment

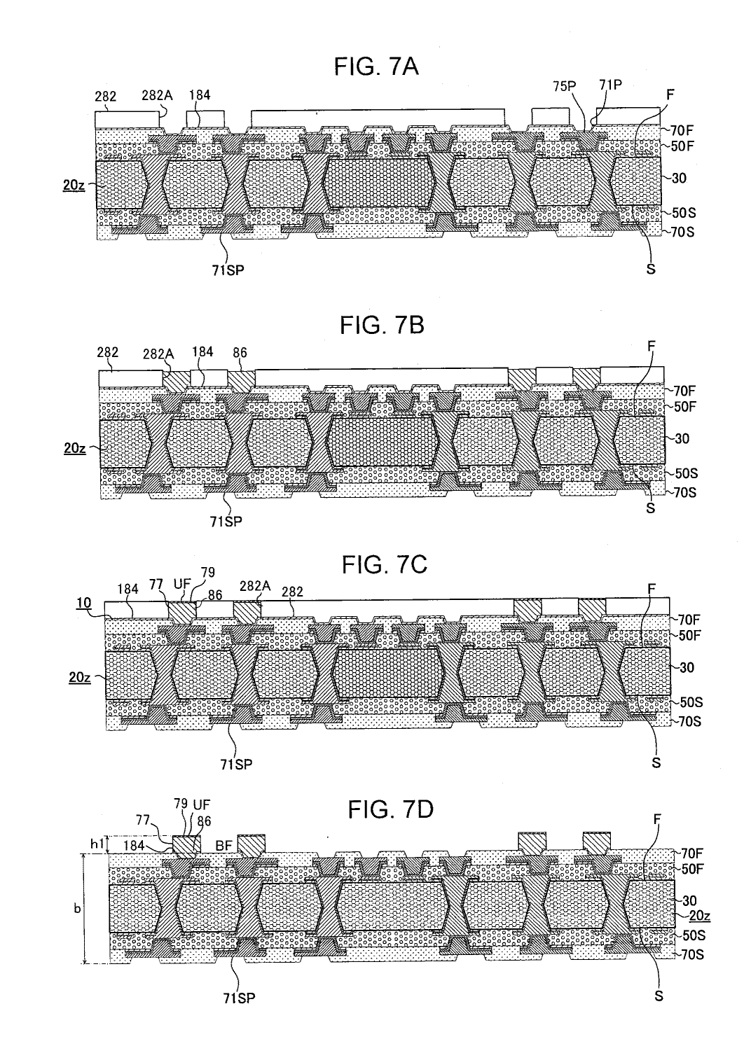

A printed wiring board of a second embodiment is illustrated in FIG. 7D.

Similar to the first embodiment, a metal post of the printed wiring board of the second embodiment has a seed layer 184 of a lower surface (BF). An electrolytic copper plating film 86 is formed on an upper side of the seed layer 184. The electrolytic copper plating film 86 on a portion of the side wall of the metal post that protrudes from the upper side solder resist layer is exposed. On the protruding portion of the metal post, a seed layer is not formed.

In the following, a method for manufacturing the printed wiring board of the second embodiment is illustrated.

Similar to the first embodiment, the lower substrate 101 is formed (FIG. 6C). Then, a seed layer 184 is formed on the upper side solder resist layer 70 and in the openings (71P, 71I) by sputtering (FIG. 6D). The seed layer is formed by a Ti film and a Cu film on the Ti film. The seed layer can be formed by electroless copper plating. The BGA pad and the lower side solder resist layer are covered by a protective sheet. However, the protective sheet is not depicted in the drawings.

A plating resist 282 is formed on the seed layer 184, having an opening (282A) for exposing the seed layer that is formed on the second pad (75P) and on the solder resist layer around the pad (75P) (FIG. 7A). The opening (282A) has a size larger than that of the second pad.

A current is applied via the seed layer 184, and an electrolytic plating film 86 is formed in the opening (282A) (FIG. 7B). A protective film 79 is formed on the upper surface (UF) of the metal post 77 (FIG. 7C). The protective film has a thickness of about 2 μm. The thickness of the protective film 79 is included in the height (h1) of the metal post.

The plating resist 282 is removed. The seed layer 184 that is exposed from the metal post is removed by etching. The protective sheet is removed. The printed wiring board 10 of the second embodiment is completed (FIG. 7D). When the protective film is not formed in FIG. 7C, the plating resist 282 and the seed layer that is exposed from the metal post are removed. Thereafter, the protective film is formed on the side wall of the metal post and on the upper surface of the metal post.

In the second embodiment, the ratio (h1/b) of the height (h1) of the metal post to the thickness (distance) (b) of the first circuit substrate is greater than 0.1 and smaller than 1.0. The ratio (h1/b) is 0.3. Therefore, the second embodiment has the same effect as the first embodiment.

In a POP package described in U.S. Pat. No. 7,723,834B2, it is expected that physical properties of the semiconductor packages do not match, and thermal stress acts on the lead line. Due to the thermal stress, connection reliability between the semiconductor packages may be decreased.

A POP substrate according to an embodiment of the present invention has high connection reliability. A printed wiring board according to another embodiment of the present invention has a metal post structure which provides a POP substrate having high reliability.

A printed wiring board according to an embodiment of the present invention includes a first circuit substrate that has a first pad for mounting an electronic component and a second pad for electrically connecting to a second circuit substrate, and a metal post that is formed by plating and is formed on the second pad for mounting the second circuit substrate. A value (h1/b) obtained by dividing a height (h1) of the metal post by a thickness (b) of the first circuit substrate is greater than 0.1 and smaller than 1.0.

Obviously, numerous modifications and variations of the present invention are possible in light of the above teachings. It is therefore to be understood that within the scope of the appended claims, the invention may be practiced otherwise than as specifically described herein.

What is claimed is:

1. A printed wiring board, comprising:
a first circuit substrate comprising a plurality of first pads and a plurality of second pads such that the plurality of first pads is positioned to mount an electronic component on the first circuit substrate and that the plurality of second pads is positioned to electrically connect the first circuit substrate to a second circuit substrate; and
a plurality of metal posts comprising plating material and formed on the plurality of second pads respectively such that the plurality of metal posts is positioned to mount the second circuit substrate on the first circuit substrate,
wherein each of the metal posts has a height h1 and a thickness b such that the plurality of metal posts has a value h1/b which is greater than 0.1 and smaller than 1.0 where the value h1/b is obtained by dividing the height h1 by the thickness b.

2. A printed wiring board according to claim 1, wherein each of the metal posts has an upper surface and a lower surface on an opposite side of the upper surface such that the lower surface of each of the metal posts is facing a respective one of the second pads, and the upper surface of each of the metal posts has a concave portion.

3. A printed wiring board according to claim 1, wherein each of the metal posts comprises a seed layer and an electrolytic copper plating portion formed on the seed layer.

4. A printed wiring board according to claim 1, wherein the plurality of second pads is formed such that the second pads have a pitch of 0.3 mm or less between adjacent second pads.

5. A printed wiring board according to claim 1, wherein each of the metal posts has an upper surface and a lower surface on an opposite side of the upper surface such that the lower surface of each of the metal posts is facing a respective one of the second pads and has a diameter d1 and a distance H between the upper surface and the lower surface such that the plurality of metal posts has a ratio H/d1 which is greater than 0.6 and less than 1.5.

6. A printed wiring board according to claim 2, wherein each of the metal posts comprises a seed layer and an electrolytic copper plating portion formed on the seed layer.

7. A printed wiring board according to claim 2, wherein the plurality of second pads is formed such that the second pads have a pitch of 0.3 mm or less between adjacent second pads.

8. A printed wiring board according to claim 2, wherein each of the metal posts has an upper surface and a lower surface on an opposite side of the upper surface such that the lower surface of each of the metal posts is facing a respective one of the second pads and has a diameter d1 and a distance H between the upper surface and the lower surface such that the plurality of metal posts has a ratio H/d1 which is greater than 0.6 and less than 1.5.

9. A printed wiring board according to claim 3, wherein the plurality of second pads is formed such that the second pads have a pitch of 0.3 mm or less between adjacent second pads.

10. A printed wiring board according to claim 3, wherein each of the metal posts has an upper surface and a lower surface on an opposite side of the upper surface such that the lower surface of each of the metal posts is facing a respective one of the second pads and has a diameter d1 and a distance H between the upper surface and the lower surface such that the plurality of metal posts has a ratio H/d1 which is greater than 0.6 and less than 1.5.

11. A printed wiring board according to claim 4, wherein each of the metal posts has an upper surface and a lower surface on an opposite side of the upper surface such that the lower surface of each of the metal posts is facing a respective one of the second pads and has a diameter d1 and a distance H between the upper surface and the lower surface such that the plurality of metal posts has a ratio H/d1 which is greater than 0.6 and less than 1.5.

12. A printed wiring board according to claim 6, wherein the plurality of second pads is formed such that the second pads have a pitch of 0.3 mm or less between adjacent second pads.

13. A printed wiring board according to claim 6, wherein each of the metal posts has an upper surface and a lower surface on an opposite side of the upper surface such that the lower surface of each of the metal posts is facing a respective one of the second pads and has a diameter d1 and a distance H between the upper surface and the lower surface such that the plurality of metal posts has a ratio H/d1 which is greater than 0.6 and less than 1.5.

14. A printed wiring board according to claim 7, wherein each of the metal posts has an upper surface and a lower surface on an opposite side of the upper surface such that the lower surface of each of the metal posts is facing a respective one of the second pads and has a diameter d1 and a distance H between the upper surface and the lower surface such that the plurality of metal posts has a ratio H/d1 which is greater than 0.6 and less than 1.5.

15. A printed wiring board according to claim 1, wherein the first circuit comprises a plurality of BGA pads positioned to connect the first circuit substrate to a mother board on an opposite side of the first circuit substrate with respect to the plurality of first pads and the plurality of second pads.

16. A package on package substrate, comprising:
a printed wiring board;
a second circuit substrate mounted on the printed wiring board; and
an electronic component mounted on the printed wiring board such that the electronic component is positioned in a space formed between the printed wiring board and the second circuit substrate,
wherein the printed wiring board comprises a first circuit substrate comprising a plurality of first pads and a plurality of second pads such that the plurality of first pads is positioned to mount the electronic component on the first circuit substrate and that the plurality of second pads is positioned to electrically connect the printed wiring board to the second circuit substrate, and a plurality of metal posts comprising plating material and formed on the plurality of second pads respectively such that the plurality of metal posts is positioned to mount the second circuit substrate on the first circuit substrate, and each of the metal posts has a height h1 and a thickness b such that the plurality of metal posts has a value h1/b which is greater than 0.1 and smaller than 1.0 where the value h1/b is obtained by dividing the height h1 by the thickness b.

17. A package on package substrate according to claim 16, wherein each of the metal posts has an upper surface and a lower surface on an opposite side of the upper surface such that the lower surface of each of the metal posts is facing a respective one of the second pads, and the upper surface of each of the metal posts has a concave portion.

18. A package on package substrate according to claim 16, wherein each of the metal posts comprises a seed layer and an electrolytic copper plating portion formed on the seed layer.

19. A package on package substrate according to claim 16, wherein the plurality of second pads is formed such that the second pads have a pitch of 0.3 mm or less between adjacent second pads.

20. A package on package substrate according to claim 16, wherein each of the metal posts has an upper surface and a lower surface on an opposite side of the upper surface such that the lower surface of each of the metal posts is facing a respective one of the second pads and has a diameter d1 and a distance H between the upper surface and the lower surface such that the plurality of metal posts has a ratio H/d1 which is greater than 0.6 and less than 1.5.
